(19) United States
(12) Patent Application Publication
(10) Pub. No.: US 2025/0067612 A1
(43) Pub. Date: Feb. 27, 2025

(54) PRESSURE SENSOR DEVICE

(71) Applicant: Murata Manufacturing Co., Ltd., Nagaokakyo-shi (JP)

(72) Inventor: Gou SAITOU, Nagaokakyo-shi (JP)

(21) Appl. No.: 18/947,345

(22) Filed: Nov. 14, 2024

Related U.S. Application Data
(63) Continuation of application No. PCT/JP2023/022062, filed on Jun. 14, 2023.

(30) Foreign Application Priority Data
Jul. 5, 2022 (JP) 2022-108535

(51) Int. Cl. G01L 19/00; G01L 9/00

(52) U.S. Cl. CPC G01L 19/0046; G01L 9/0052; G01L 9/0072

(57) ABSTRACT

A pressure sensor device that includes: a base substrate; a detecting element mounted on an upper surface of the base substrate and that includes a detecting portion that detects pressure; a resin package on the upper surface of the base substrate and that has an exposure hole that exposes the detecting portion, the detecting element being embedded in the resin package; and an on-off valve disposed so as to close the exposure hole, the on-off valve including: a membrane having an outer surface facing an outside of the pressure sensor device, and a communication path that is partly formed by an inner surface of the membrane and allows the detecting portion to communicate with the outside of the pressure sensor device, the inner surface being opposite the outer surface, and wherein the inner surface closes the communication path when the membrane is flexed by pressure acting upon the outer surface.

### CROSS REFERENCE TO RELATED APPLICATIONS

The present application is a continuation of International application No. PCT/JP2023/022062, filed Jun. 14, 2023, which claims priority to Japanese Patent Application No. 2022-108535, filed Jul. 5, 2022, the entire contents of each of which are incorporated herein by reference.

### TECHNICAL FIELD

The present disclosure relates to a pressure sensor device that detects pressure.

### BACKGROUND ART

Patent Document 1 discloses a semiconductor device that detects pressure. The semiconductor device includes a detecting element that is provided on a base substrate, and a resin package that is provided on the base substrate and in which the detecting element is embedded. The detecting element includes a detecting portion that detects pressure. The resin package has an exposure hole for exposing the detecting portion to the outside. Since the detecting portion is exposed to the outside through the exposure hole, the detecting portion is capable of detecting pressure that acts from the outside.
Patent Document 1: International Publication No. 2019/208127

### SUMMARY OF THE DISCLOSURE

In the semiconductor device disclosed in Patent Document 1, since the detecting portion is exposed to the outside through the exposure hole, a liquid, such as water, may reach the detecting portion through the exposure hole. When the liquid that has reached the detecting portion dries, residue remains on the detecting portion. This residue may reduce the precision of the pressure that is detected by the detecting portion. For example, although the detecting portion detects pressure in accordance with a flexing amount resulting from pressure that acts, when any residue exists on the detecting portion, the detecting portion is brought into a flexed state even when pressure does not act. Therefore, the characteristics of the pressure that is detected may be shifted with respect to the proper characteristics. In addition, for example, the residue on the detecting portion may restrict deformation of the detecting portion. In this case, the sensitivity of the detecting portion with respect to the pressure that acts may change.

Therefore, an object of the present disclosure is to solve the problems above and to provide a pressure sensor device that is capable of reducing how frequently a liquid reaches a detecting portion.

To this end, the present disclosure has the following structure.

A pressure sensor device according to an aspect of the present disclosure includes: a base substrate; a detecting element mounted on an upper surface of the base substrate and that includes a detecting portion that detects pressure; a resin package on the upper surface of the base substrate and that has an exposure hole that exposes the detecting portion, the detecting element being embedded in the resin package; and an on-off valve disposed so as to close the exposure hole, wherein the on-off valve includes: a membrane that includes an outer surface facing an outside of the pressure sensor device, and a communication path that is partly formed by an inner surface of the membrane and allows the detecting portion to communicate with the outside of the pressure sensor device, the inner surface being opposite the outer surface, and wherein the inner surface closes the communication path when the membrane is flexed by pressure that acts upon the outer surface.

According to the present disclosure, it is possible to suppress a liquid from reaching the detecting portion.

### BRIEF DESCRIPTION OF THE DRAWINGS

FIG. 1 is a plan view of a pressure sensor device according to a first embodiment of the present disclosure.

FIG. 2 is a sectional view along line A-A of FIG. 1.

FIG. 3 is a sectional view corresponding to that along line A-A of FIG. 1 of a pressure sensor device according to a second embodiment of the present disclosure.

FIG. 4 is a plan view of a pressure sensor device according to a third embodiment of the present disclosure.

FIG. 5 is a sectional view along line B-B of FIG. 4.

FIG. 6 is a sectional view corresponding to a position along line B-B of FIG. 4 of a pressure sensor device according to a fourth embodiment of the present disclosure.

### DESCRIPTION OF THE PREFERRED EMBODIMENTS

### First Embodiment

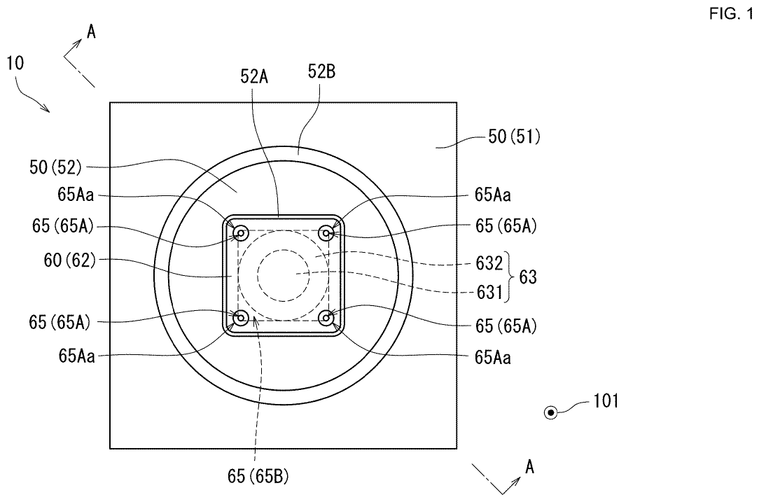

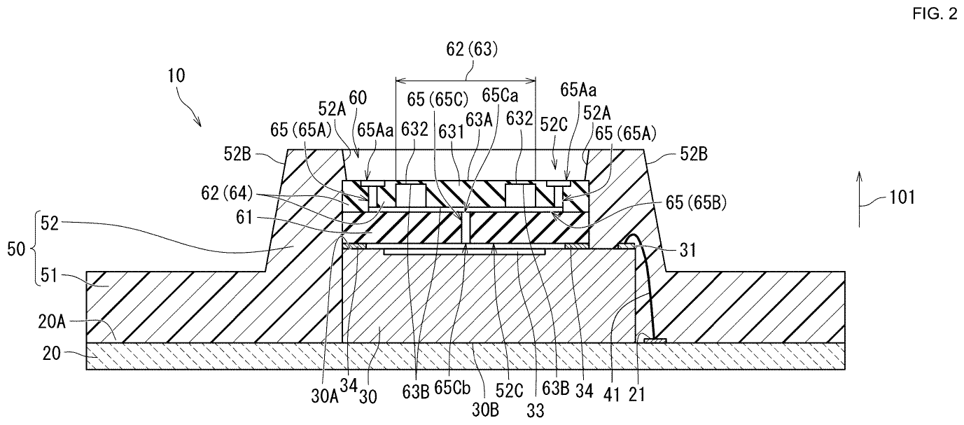

FIG. 1 is a plan view of a pressure sensor device according to a first embodiment of the present disclosure. FIG. 2 is a sectional view along line A-A of FIG. 1. Although, in the description below, for convenience of explanation, terms indicating directions, such as “up” and “down”, are used, these terms do not limit, for example, the state of use of the pressure sensor device according to the present disclosure.

A pressure sensor device 10 is an element that detects pressure. As shown in FIGS. 1 and 2, the pressure sensor device 10 includes a base substrate 20, a detecting element 30 that is mounted on an upper surface 20A of the base substrate 20 and that detects pressure, and a resin package 50 that is provided on the upper surface 20A of the base substrate 20 and that covers a part of the detecting element 30.

In the first embodiment, although the base substrate 20 is a rigid substrate made of ceramic, the base substrate 20 is not limited thereto. For example, the base substrate 20 may be a rigid substrate made of a material other than ceramic, such as glass epoxy. Alternatively, the base substrate 20 may be, for example, a lead frame instead of a rigid substrate.

In the first embodiment, the base substrate 20 has a thin rectangular parallelepiped shape in an up-down direction 101. That is, in the first embodiment, the base substrate 20 has a square shape in plan view thereof, in other words, has a square shape as viewed from the up-down direction 101. Note that the shape of the base substrate 20 is not limited to a rectangular parallelepiped shape (shape that is a square shape as viewed from the up-down direction 101). For example, the base substrate 20 may have a shape other than a square shape, that is, a polygonal shape as viewed from the up-down direction 101.

As shown in FIG. 2, an electrode 21 is formed on the upper surface 20A of the base substrate 20. Although FIG. 2 shows one electrode, a plurality of electrodes may be used instead of one electrode.

The electrode 21 is electrically connected to a circuit element (not shown). The circuit element may be mounted on the base substrate 20, or may be provided at an outer portion of the base substrate 20. The circuit element is, for example, an element including an application specific integrated circuit (ASIC) for specific applications.

The circuit element includes, for example, a signal processing circuit that processes a signal that has been input from the detecting element 30 (described later) through the electrode 21, and outputs the processed signal. For example, the circuit element includes a converter, a filter, a temperature sensor, a processor, and a memory. The converter converts a voltage signal that has been input from the detecting element 30 into a digital signal. The filter filters the digital signal coming from the converter. The temperature sensor detects the temperature. The processor corrects the filtered digital signal based on the detected temperature of the temperature sensor. The memory stores, for example, a correction coefficient used when correcting the digital signal by using the detected temperature.

In the first embodiment, the detecting element 30 is a pressure sensor for measuring pressure. As shown in FIG. 2, the detecting element 30 has an upper surface 30A and a lower surface 30B that is a back side of the upper surface 30A. The detecting element 30 is, for example, a piezoresistive pressure sensor or an electrostatic capacitance pressure sensor. The detecting element 30 constitutes, together with an on-off valve 60 (described below), micro electro mechanical systems (MEMS). That is, the detecting element 30 and the on-off valve 60 are the MEMS.

In the case of the first embodiment, the lower surface 30B of the detecting element 30 is adhered to the upper surface 20A of the base substrate 20 by using, for example, a die attach film or a die attach material. Therefore, the detecting element 30 is mounted on the upper surface 20A of the base substrate 20. Note that the detecting element 30 may be mounted on the base substrate 20 by, for example, solder. By using, for example, a die attach film or a die attach material, the detecting element 30 may be adhered to and mounted on the circuit element mounted on the base substrate 20.

The detecting element 30 includes at the upper surface 30A a detecting portion 33 upon which pressure acts. The detecting portion 33 detects pressure. The detecting portion 33 of the detecting element 30 is a membrane or a diaphragm that receives pressure. Note that the detecting portion 33 includes, for example, a passivation film, and is water-resistant.

An electrode 31 is formed on the upper surface 30A of the detecting element 30. Although FIG. 2 shows one electrode, a plurality of electrodes may be used instead of one electrode.

The electrode 31 is electrically connected to the electrode 21 on the base substrate 20 through a bonding wire 41. The detecting element 30 outputs to the outside from the electrode 31 a signal corresponding to the pressure detected by the detecting portion 33. That is, the signal corresponding to the pressure detected by the detecting portion 33 is output to the circuit element through the electrode 31 and the bonding wire 41.

The resin package 50 is formed by molding, for example, thermosetting resin, such as hard resin or epoxy mold resin, on the upper surface 20A of the base substrate 20. That is, as shown in FIG. 2, the resin package 50 is provided on the upper surface 20A of the base substrate 20. The upper surface 20A of the base substrate 20 and the electrode 21 formed on the upper surface 20A are made water-resistant while being protected by being covered by the resin package 50.

The detecting element 30 and the bonding wire 41 are embedded in the resin package 50. By embedding the detecting element 30 and the bonding wire 41 in the resin package 50, the detecting element 30 and the bonding wire 41 are made water-resistant while being protected.

As shown in FIGS. 1 and 2, the resin package 50 includes a base portion 51 and a cylindrical portion 52.

The base portion 51 constitutes, of the resin package 50, a base-substrate-20 side. That is, the base portion 51 constitutes a lower portion of the resin package 50. As shown in FIG. 2, the base portion 51 is in contact with the upper surface 20A of the base substrate 20. That is, the base portion 51 is provided on the upper surface 20A of the base substrate 20.

In the first embodiment, the base portion 51 has a thin rectangular parallelepiped shape in the up-down direction 101. That is, in the first embodiment, the base portion 51 has a square shape as viewed from the up-down direction 101. As viewed from the up-down direction 101, the base portion 51 and the base substrate 20 have the same shape and the same size. That is, in the first embodiment, the base portion 51 covers the entire upper surface 20A of the base substrate 20.

Note that the shape of the base portion 51 is not limited to a rectangular parallelepiped shape (shape that is a square shape as viewed from the up-down direction 101). For example, the base portion 51 may have a shape other than a square shape, that is, a polygonal shape or a circular shape as viewed from the up-down direction 101. As viewed from the up-down direction 101, the base portion 51 and the base substrate 20 may have different shapes or may have different sizes. That is, the base portion 51 may cover only a part of the upper surface 20A of the base substrate 20.

The cylindrical portion 52 constitutes, of the resin package 50, a side opposite to the base substrate 20 with respect to the base portion 51. That is, the cylindrical portion 52 constitutes an upper portion of the resin package 50. The cylindrical portion 52 projects from the base portion 51 so as to extend away from the base substrate 20. In other words, the cylindrical portion 52 projects upward from the base portion 51.

As shown in FIG. 1, as viewed from the up-down direction 101, an outer side surface 52B of the cylindrical portion 52 is positioned inward from the base portion 51. In other words, as shown in FIGS. 1 and 2, the base portion 51 projects outward from the outer side surface 52B of the cylindrical portion 52. Note that, in the first embodiment, as shown in FIG. 1, the base portion 51 extends outward from the outer side surface 52B over the entire periphery of the outer side surface 52B of the cylindrical portion 52. However, the base portion 51 may extend outward from the outer side surface 52B over only a part of the periphery of the outer side surface 52B of the cylindrical portion 52 instead of over the entire periphery of the outer side surface 52B of the cylindrical portion 52.

As shown in FIGS. 1 and 2, the cylindrical portion 52 has an exposure hole 52C. The exposure hole 52C extends through the cylindrical portion 52 in the up-down direction 101 and is formed by an inner side surface 52A of the cylindrical portion 52. Therefore, the cylindrical portion 52 has a cylindrical shape.

Although, as shown in FIG. 1, as viewed from the up-down direction 101, the exposure hole 52C has a square shape, the exposure hole 52C may have other shapes, such as a circular shape.

As shown in FIG. 2, a part of the upper surface 30A of the detecting element 30 and the detecting portion 33 face the exposure hole 52C. That is, a part of the upper surface 30A of the detecting element 30 and the detecting portion 33 are exposed to an upper side through the exposure hole 52C. In other words, the exposure hole 52C allows the detecting portion 33 to be exposed to the upper side.

As shown in FIGS. 1 and 2, the pressure sensor device 10 includes the on-off valve 60, in addition to the base substrate 20, the detecting element 30, and the resin package 50.

As shown in FIG. 2, the on-off valve 60 is disposed so as to close the exposure hole 52C. Therefore, the upper side of the detecting portion 33 is covered by the on-off valve 60.

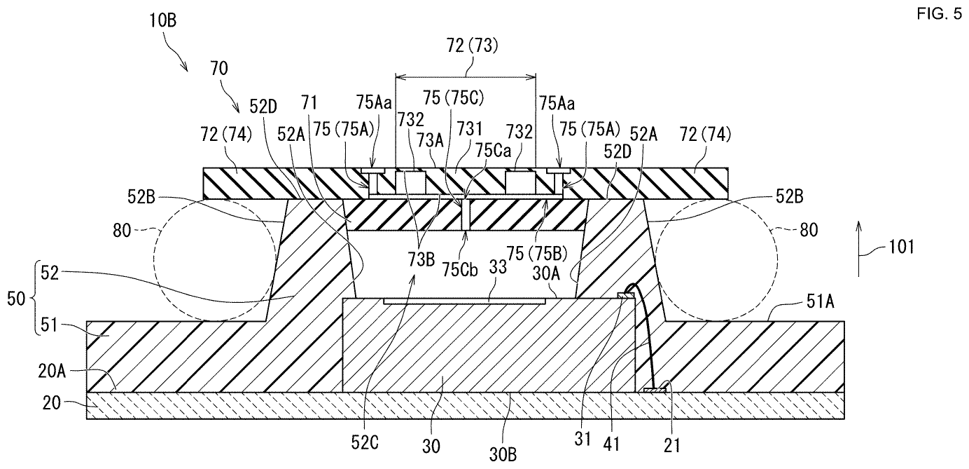

The on-off valve 60 is disposed in a lower portion of the exposure hole 52C. In the first embodiment, the on-off valve 60 is supported by a support film 34 formed on the upper surface 30A of the detecting element 30. The support film 34 is an adhesive that joins the detecting element 30 and the on-off valve 60 to each other, and is made of, for example, polycrystalline silicon. Note that the position where the on-off valve 60 is disposed in the exposure hole 52C is not limited to the lower portion of the exposure hole 52C. For example, similarly to an on-off valve 70 (described below) (see FIG. 5), the on-off valve 60 may be disposed in an upper portion of the exposure hole 52C.

The on-off valve 60 includes a lower part 61 that opposes the detecting element 30 in the up-down direction 101, and an upper part 62 that is provided on an upper side of the lower part 61 and that faces the outside of the pressure sensor device 10.

The upper part 62 includes a membrane 63 and a peripheral edge portion 64. As viewed from the up-down direction 101, the membrane 63 is formed at a central portion of the upper part 62. As viewed from the up-down direction 101, the peripheral edge portion 64 is formed so as to surround the membrane 63. A lower surface of the peripheral edge portion 64 is joined to the lower part 61.

An upper surface 63A of the membrane 63 faces the outside of the pressure sensor device 10. The upper surface 63A is an example of an outer surface. A lower surface 63B of the membrane 63 is a back side of the upper surface 63A, and is positioned at an inner portion of the upper part 62. The lower surface 63B opposes the lower part 61 in the up-down direction 101 with an inner space 65B (described below) being interposed therebetween. The lower surface 63B is an example of an inner surface.

The membrane 63 includes a thick film portion 631 and a thin film portion 632. The thick film portion 631 is thicker than the thin film portion 632. The thickness of the thick film portion 631 and the thickness of the thin film portion 632 are the length of the thick film portion 631 and the length of the thin film portion 632 in the up-down direction 101. As viewed from the up-down direction 101, the thick film portion 631 is positioned at a central portion of the membrane 63. As viewed from the up-down direction 101, the thin film portion 632 is provided so as to surround the thick film portion 631. The thin film portion 632 is connected to the peripheral edge portion 64.

A communication path 65 is formed in the on-off valve 60. The communication path 65 allows the detecting portion 33 to communicate with the outside of the pressure sensor device 10. That is, while the on-off valve 60 closes the exposure hole 52C, the on-off valve 60 allows the detecting portion 33 to communicate with the outside of the pressure sensor device 10 through the communication path 65.

The communication path 65 includes upper through holes 65A that are formed in the upper part 62, the inner space 65B that is formed between the upper part 62 and the lower part 61, and a lower through hole 65C that is formed in the lower part 61.

Each upper through hole 65A is formed in the peripheral edge portion 64 of the upper part 62. That is, each upper through hole 65A is formed on an outer side of the membrane 63 as viewed from the up-down direction 101. As shown in FIG. 1, four upper through holes 65A are formed in the upper part 62. However, the number of upper through holes 65A is not limited to four.

Each upper through hole 65A extends through the peripheral edge portion 64 in the up-down direction 101. Each upper through hole 65A communicates with the inner space 65B. Each upper through hole 65A communicates with the outside of the pressure sensor device 10 through openings 65Aa. Therefore, each upper through hole 65A allows the inner space 65B to communicate with the outside of the pressure sensor device 10. Note that, in the first embodiment, the diameter of each opening 65Aa is larger than the diameter of each upper through hole 65A.

The inner space 65B is formed directly below the membrane 63 of the upper part 62. That is, the inner space 65B is formed between the membrane 63 and the lower part 61. That is, a part of the inner space 65B is formed by the lower surface 63B of the membrane 63, and another part of the inner space 65B is formed by the lower part 61. Note that the inner space 65B may extend up to a location directly below the peripheral edge portion 64 in addition to extending directly below the membrane 63.

The lower through hole 65C extends through the lower part 61 in the up-down direction 101. The lower through hole 65C includes an upper side opening 65Ca that opens into the inner space 65B, and a lower side opening 65Cb that opens into a space of the exposure hole 52C between the lower part 61 and the detecting portion 33. The upper side opening 65Ca opposes the membrane 63 in the up-down direction 101. In other words, the upper side opening 65Ca overlaps the membrane 63 as viewed from the up-down direction 101. The lower side opening 65Cb opens toward the detecting portion 33. Therefore, the lower through hole 65C allows the inner space 65B to communicate with the detecting portion 33. In the first embodiment, the lower part 61 has one lower through hole 65C. However, the number of lower through holes 65C is not limited to one and may be more than one.

An operation of the on-off valve 60 is described below.

Excessive pressure may act upon the upper surface 63A of the membrane 63 of the on-off valve 60. For example, when a liquid, such as water, that has entered the exposure hole 52C of the pressure sensor device 10 from above the exposure hole 52C comes into contact with the upper surface 63A of the membrane 63, excessive pressure acts upon the upper surface 63A of the membrane 63.

In this case, the membrane 63 flexes downward by the pressure that has acted upon the upper surface 63A. In detail, the thick film portion 631 that, as viewed from the up-down direction 101, is positioned at the central portion of the membrane 63 flexes by a larger amount than the thin film portion 632 that, as viewed from the up-down direction 101, is positioned so as to surround the thick film portion 631 and is connected to the peripheral edge portion 64. The thick film portion 631 of the membrane 63 that has flexed downward comes into contact with the upper side opening 65Ca of the lower through hole 65C that opens into the inner space 65B of the communication path 65, and closes the upper side opening 65Ca. Therefore, the communication path 65 is closed. That is, of the lower surface 63B of the membrane 63, the lower surface 63B at the thick film portion 631 closes the communication path 65.

On the other hand, a liquid, such as water, that has entered the exposure hole 52C of the pressure sensor device 10 from above the exposure hole 52C may enter the upper through holes 65A from the openings 65Aa formed in the upper part 62 of the on-off valve 60. However, the liquid that has entered the upper through holes 65A passes through the upper through holes 65A and reaches the inner space 65B, but does not enter the lower through hole 65C.

This is because the thick film portion 631 of the membrane 63 that has flexed downward by the pressure that has acted upon the upper surface 63A of the membrane 63 closes the upper side opening 65Ca before the liquid that has entered the upper through holes 65A reaches the upper side opening 65Ca. The position of the upper side opening 65Ca is an example of a closing position.

The on-off valve 60 is formed such that the thick film portion 631 of the membrane 63 that has flexed downward by the pressure that has acted upon the upper surface 63A of the membrane 63 closes the upper side opening 65Ca before the liquid that has entered the upper through holes 65A reaches the upper side opening 65Ca. For example, in the first embodiment, since the membrane 63 includes the thick film portion 631, the membrane 63 is formed to flex faster than a structure in which the membrane 63 does not include a thick film portion 631. For example, in the first embodiment, since the membrane 63 includes the thick film portion 631 and the thin film portion 632, a space that is longer in the up-down direction 101 than other portions is formed directly below the thin film portion 632 at the inner space 65B. Since the space exists, the time taken for a liquid that has entered the inner space 65B to reach the upper side opening 65Ca through the space can be made longer than in a structure that does not include the space.

According to the first embodiment, when a liquid, such as water, has come into contact with the upper surface 63A of the membrane 63, excessive pressure may act upon the upper surface 63A of the membrane 63 from the liquid due to, for example, the weight of the liquid. When excessive pressure acts upon the upper surface 63A of the membrane 63, the membrane 63 flexes. Therefore, the lower surface 63B of the membrane 63 closes the communication path 65. In order to bring the liquid into contact with the detecting portion 33, the liquid needs to pass through the communication path 65. However, as described above, the communication path 65 is closed by the lower surface 63B of the membrane 63. Therefore, the liquid that has entered the communication path 65 from the outside of the pressure sensor device 10 can be suppressed from reaching the detecting portion 33 by passing through the communication path 65. As a result, it is possible suppress production of residue of the liquid on the detecting portion 33 and changes in the detection characteristics of the detecting portion 33 caused by the residue.

Note that, when a gas comes into contact with the upper surface 63A of the membrane 63 and pressure that is not excessive acts upon the upper surface 63A of the membrane 63, the flexing amount of the membrane 63 is small, as a result of which the gas passes through the communication path 65 and reaches the detecting portion 33. Therefore, the detecting portion 33 is capable of detecting the pressure of the gas.

According to the first embodiment, since the lower surface 63B of the membrane 63 closes the upper side opening 65Ca of the lower through hole 65C, the communication path 65 is closed. Here, the upper side opening 65Ca opens into the inner space 65B. Therefore, the area of the upper side opening 65Ca is smaller than the area of the inner space 65B in the plan view. Consequently, it is easier to close the upper side opening 65Ca than the inner space 65B. Thus, according to the first embodiment, it is possible to easily close the communication path 65.

According to the first embodiment, the central portion of the membrane 63 that is constituted by the thick film portion 631 is thicker than a peripheral edge portion of the membrane 63 that is constituted by the thin film portion 632. Therefore, the central portion of the membrane 63 is heavier than the peripheral edge portion of the membrane 63. Consequently, when pressure acts upon the upper surface 63A of the membrane 63, the membrane 63 is likely to flex. Thus, the communication path 65 can be easily and quickly closed by the membrane 63.

If the thickness of the membrane 63 is uniform, the pressure of a liquid that enters the communication path 65 and acts upon the lower surface 63B of the membrane 63 and the pressure of a liquid that acts upon the upper surface 63A of the membrane 63 from the outside are in equilibrium, and thus there is a possibility that the membrane 63 will not flex. However, according to the first embodiment, since the membrane 63 includes the thick film portion 631 and the thin film portion 632, the thickness of the membrane 63 is not uniform. Therefore, it is possible to reduce that possibility that the membrane 63 will not flex occurring when the pressure of a liquid that acts upon the lower surface 63B of the membrane 63 and the pressure of a liquid that acts upon the upper surface 63A of the membrane 63 are in equilibrium with each other.

According to the first embodiment, the thick film portion 631 of the membrane 63 that has flexed downward by the pressure that has acted upon the upper surface 63A of the membrane 63 closes the upper side opening 65Ca before the liquid that has entered the upper through holes 65A reaches the upper side opening 65Ca. Therefore, it is possible to prevent the liquid from passing through the communication path 65 before the lower surface 63B of the membrane 63 closes the communication path 65. As a result, it is possible to suppress the liquid from reaching the detecting portion 33.

According to the first embodiment, since the on-off valve 60, together with the detecting element 30, constitutes the MEMS, it is possible to manufacture the on-off valve 60 by a technology for processing the MEMS. Therefore, it is possible for the on-off valve 60 to have high processing precision that does not depend upon the molding precision of the resin package 50. As a result, it is possible to suppress a liquid from reaching the detecting portion 33 through the on-off valve 60 from the outside of the pressure sensor device 10.

### Second Embodiment

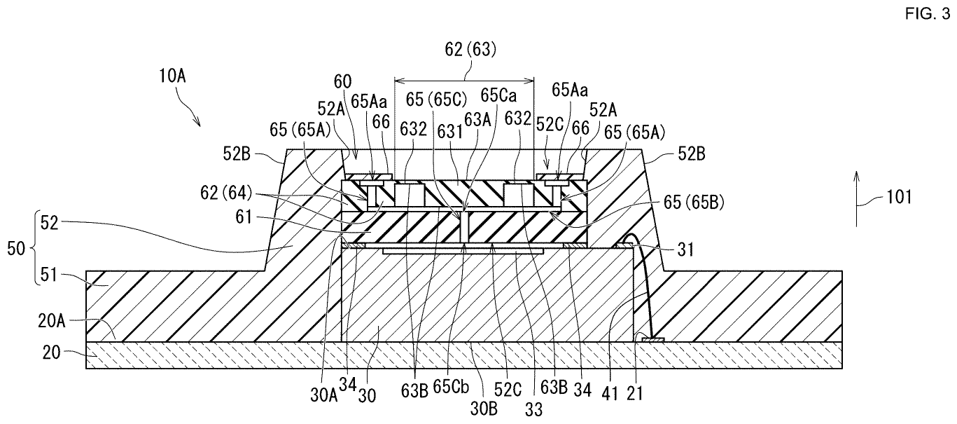

FIG. 3 is a sectional view corresponding to that along line A-A of FIG. 1 of a pressure sensor device according to a second embodiment of the present disclosure. A pressure sensor device 10A according to the second embodiment differs from the pressure sensor device 10 according to the first embodiment in that the pressure sensor device 10A includes a closing film 66. The differences from the first embodiment are described below. Descriptions of similarities to the pressure sensor device 10 according to the first embodiment are in general omitted and given when necessary while the same reference numerals are used.

As shown in FIG. 3, an on-off valve 60 is provided with the closing film 66. The closing film 66 is laminated on an upper side of a peripheral edge portion 64 of an upper part 62 of the on-off valve 60. The closing film 66 covers openings 65Aa. That is, the closing film 66 closes openings of a communication path 65 that communicate with the outside of the pressure sensor device 10A. Note that, in FIG. 3, the closing film 66 is provided on the peripheral edge portion 64 of the upper part 62 and covers the openings 65Aa. However, the range in which the closing film 66 is provided is not limited to the range shown in FIG. 3. For example, the closing film 66 may cover both the peripheral edge portion 64 and a membrane 63, that is, an entire upper surface of the upper part 62 in a range in which the behavior of the membrane 63 of the upper part 62 of the on-off valve 60 is not suppressed.

The closing film 66 is made of a material that passes a gas therethrough and does not pass a liquid therethrough. In the second embodiment, the closing film 66 is a porous film made of polytetrafluoroethylene (PTFE). Therefore, a detecting element 30 of the pressure sensor device 10A according to the second embodiment is capable of detecting the pressure of a gas that acts. On the other hand, a liquid does not act upon the detecting element 30 of the pressure sensor device 10A.

When the pressure that acts upon an upper surface 63A of the membrane 63 is negligible, the membrane 63 does not flex sufficiently, and thus there is a possibility that a lower surface 63B of the membrane 63 will not close the communication path 65. In this case, a liquid that has entered the communication path 65 of the on-off valve 60 from the outside of the pressure sensor device may pass through the communication path 65 and reach a detecting portion 33. However, according to the second embodiment, the openings 65Aa of the communication path 65 that communicate with the outside of the pressure sensor device 10A are closed by the closing film 66 that does not pass a liquid. Therefore, it is possible to suppress entry of the liquid into the communication path 65. As a result, it is possible to suppress the liquid from reaching the detecting portion 33.

### Third Embodiment

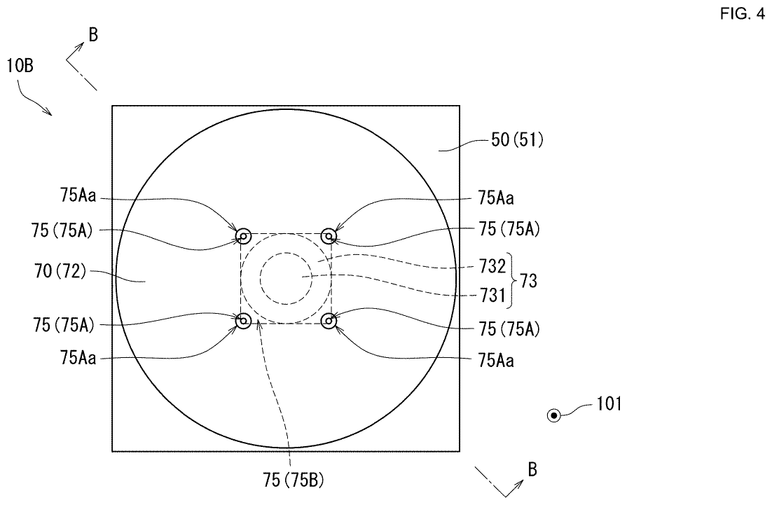

FIG. 4 is a plan view of a pressure sensor device according to a third embodiment of the present disclosure. FIG. 5 is a sectional view along line B-B of FIG. 4. A pressure sensor device 10B according to the third embodiment differs from the pressure sensor device 10 according to the first embodiment in that the pressure sensor device 10B includes an on-off valve 70 instead of the on-off valve 60. The on-off valve 70 of the pressure sensor device 10B according to the third embodiment differs from the on-off valve 60 of the pressure sensor device 10 according to the first embodiment in that a part of the on-off valve 70 extends outward from a cylindrical portion 52 of a resin package 50 as viewed from an up-down direction 101. The differences from the first embodiment are described below. Descriptions of similarities to the pressure sensor device 10 according to the first embodiment are in general omitted and given when necessary while the same reference numerals are used.

As shown in FIGS. 4 and 5, the pressure sensor device 10B includes the on-off valve 70 instead of the on-off valve 60.

As shown in FIG. 5, the on-off valve 70 is disposed at an upper portion of an exposure hole 52C. Therefore, the on-off valve 70 opposes a detecting portion 33 in an up-down direction 101 with a space that is situated at a lower portion of the exposure hole 52C being interposed therebetween. Note that the position where the on-off valve 70 is disposed at the exposure hole 52C is not limited to the upper portion of the exposure hole 52C. For example, the on-off valve 70 may be disposed over the entire region from the upper portion to the lower portion of the exposure hole 52C.

The on-off valve 70 includes an inner part 71 that is positioned at an inner portion of the exposure hole 52C and an outer part 72 that is positioned on an upper side of the exposure hole 52C and outside the exposure hole 52C.

The inner part 71 is fitted to the exposure hole 52C. The inner part 71 closes the exposure hole 52C. The inner part 71 corresponds to the lower part 61 of the on-off valve 60 of the first embodiment. Note that the inner part 71 need not be fitted to the exposure hole 52C. For example, the inner part 71 may be separated from the cylindrical portion 52. In this case, for example, the on-off valve 70 may be attached to a resin package 50 by adhering a lower surface of the outer part 72 to an upper surface 52D of the cylindrical portion 52.

The outer part 72 is positioned on an upper side of the inner part 71 and is connected to the inner part 71. In the third embodiment, the outer part 72 is integrated with the inner part 71. The outer part 72 is positioned on an upper side of the cylindrical portion 52 of the resin package 50. A part of the outer part 72 is supported by the upper surface 52D of the cylindrical portion 52. The outer part 72 corresponds to the upper part 62 of the on-off valve 60 of the first embodiment.

The outer part 72 includes a membrane 73 and a peripheral edge portion 74. As viewed from the up-down direction 101, the membrane 73 is formed at a central portion of the outer part 72. As viewed from the up-down direction 101, the peripheral edge portion 74 is formed so as to surround the membrane 73. A lower surface of the peripheral edge portion 74 is joined to the inner part 71.

The peripheral edge portion 74 of the outer part 72 extends outward from an outer side surface 52B of the cylindrical portion 52 as viewed from the up-down direction 101.

The inner part 71 has a structure that is the same as the structure of the lower part 61 of the on-off valve 60 of the first embodiment. The outer part 72 differs from the upper part 62 of the on-off valve 60 of the first embodiment in that the peripheral edge portion 74 extends outward from the outer side surface 52B of the cylindrical portion 52. With regard to the other points, the outer part 72 has structures that are the same as those of the upper part 62 of the on-off valve 60 of the first embodiment.

That is, the on-off valve 70 has a structure that is the same as the structure of the on-off valve 60 of the first embodiment except that the peripheral edge portion 74 of the outer part 72 extends outward from the outer side surface 52B of the cylindrical portion 52. Therefore, excluding the peripheral edge portion 64, each of the structural elements of the on-off valve 70 shown in FIGS. 4 and 5 is the same as each of the structural elements of the on-off valve 60 shown in FIGS. 1 and 2. Correspondence between each of the structural elements of the on-off valve 70 shown in FIGS. 4 and 5 and each of the structural elements of the on-off valve 60 shown in FIGS. 1 and 2 is described below.

The inner part 71 corresponds to the lower part 61 of the on-off valve 60 of the first embodiment. The outer part 72 corresponds to the upper part 62 of the on-off valve 60 of the first embodiment. The membrane 73 corresponds to the membrane 63 of the on-off valve 60 of the first embodiment. An upper surface 73A corresponds to the upper surface 63A of the on-off valve 60 of the first embodiment, and is an example of an outer surface. A lower surface 73B corresponds to the lower surface 63B of the on-off valve 60 of the first embodiment, and is an example of an inner surface. The peripheral edge portion 74 corresponds to the peripheral edge portion 64 of the on-off valve 60 of the first embodiment. A communication path 75 corresponds to the communication path 65 of the on-off valve 60 of the first embodiment. Upper through holes 75A correspond to the upper through holes 65A of the on-off valve 60 of the first embodiment. Openings 75Aa correspond to the openings 65Aa of the on-off valve 60 of the first embodiment. An inner space 75B corresponds to the inner space 65B of the on-off valve 60 of the first embodiment. A lower through hole 75C corresponds to the lower through hole 65C of the on-off valve 60 of the first embodiment. An upper side opening 75Ca corresponds to the upper side opening 65Ca of the on-off valve 60 of the first embodiment. A lower side opening 75Cb corresponds to the lower side opening 65Cb of the on-off valve 60 of the first embodiment.

As shown in FIG. 5, an O ring 80 shown by a broken line in FIG. 5 can be fitted to a recessed portion formed by the outer part 72, the outer side surface 52B of the cylindrical portion 52, and a base portion 51. The O ring 80 has a ring shape as viewed from the up-down direction 101. As viewed from the up-down direction 101, the inside diameter of the O ring 80 is the same as or is substantially the same as the outside diameter of the cylindrical portion 52 of the resin package 50. The O ring 80 is made of a material that is easily compressed and deformed, such as nitrile rubber.

In the structure shown in FIGS. 4 and 5, the outer part 72 extends outward from the outer side surface 52B over an entire periphery of the cylindrical portion 52 in a peripheral direction. However, the outer part 72 may extend outward from the outer side surface 52B of the cylindrical portion 52 over only a part of the cylindrical portion 52 in the peripheral direction.

In the structure shown in FIGS. 4 and 5, the inner space 75B of the communication path 75 is formed on the upper side of the cylindrical portion 52, that is, at an outer portion of the exposure hole 52C. However, the inner space 75B may be formed at an inner portion of the exposure hole 52C. In this case, for example, a lower portion of the membrane 73 of the outer part 72 is positioned at the inner portion of the exposure hole 52C.

According to the third embodiment, the on-off valve 70 can be more easily added later than in a structure in which the on-off valve 70 is disposed at the lower portion of the exposure hole 52C. Therefore, it is easy to make the on-off valve 70 an optional component that is selectably attachable to the pressure sensor device 10B.

According to the third embodiment, it is possible to fit the O ring 80 between the outer part 72 of the on-off valve 70 and the base portion 51 of the resin package 50. When the pressure sensor device 10B is attached to an apparatus, the O ring 80 seals a gap between the pressure sensor device 10B and the apparatus. According to the third embodiment, it is possible to suppress the O ring 80 from coming off by the outer part 72 of the on-off valve 70.

### Fourth Embodiment

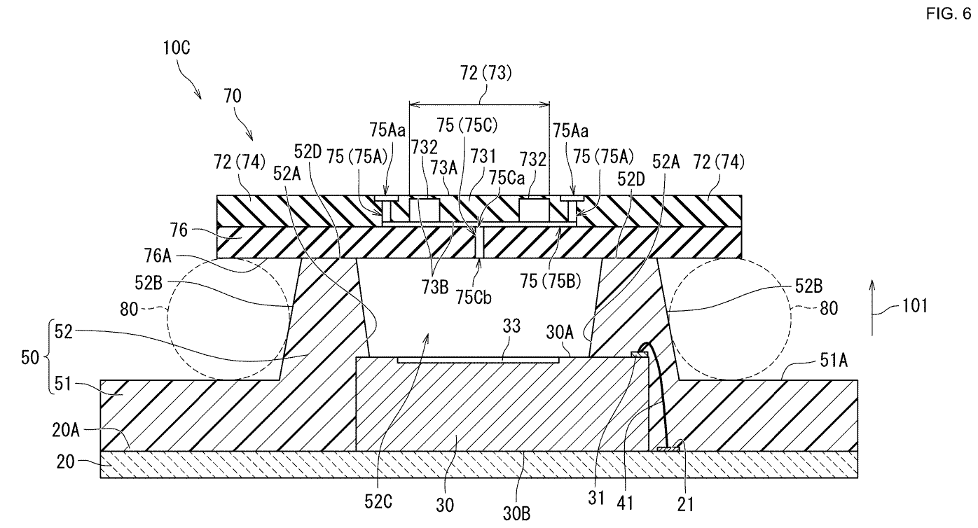

FIG. 6 is a sectional view corresponding to a position along line B-B of FIG. 4 of a pressure sensor device according to a fourth embodiment of the present disclosure. A pressure sensor device 10C according to the fourth embodiment differs from the pressure sensor device 10B according to the third embodiment in that an on-off valve 70 includes a lower part 76 instead of the inner part 71. The differences from the third embodiment are described below. Descriptions of similarities to the pressure sensor device 10B according to the third embodiment are in general omitted and given when necessary while the same reference numerals are used.

The on-off valve 70 includes the lower part 76 that is positioned outside an exposure hole 52C and an outer part 72 that is positioned outside the exposure hole 52C and that is provided on an upper side of the lower part 76. The outer part 72 of the fourth embodiment has a structure that is the same as the structure of the outer part 72 of the third embodiment.

The lower part 76 is positioned on an upper side of a cylindrical portion 52. Similarly to the outer part 72, as viewed from an up-down direction 101, the lower part 76 extends outward from an outer side surface 52B of the cylindrical portion 52. Therefore, the lower part 76 and the outer part 72 overlap both an inner side and an outer side of the cylindrical portion 52 as viewed from the up-down direction 101. Note that, although in FIG. 6, as viewed from the up-down direction 101, the lower part 76 is the same in shape and size as the outer part 72, the lower part 76 may differ in shape or size from the outer part 72. The on-off valve 70 is attached to a resin package 50. For example, the on-off valve 70 is attached to the resin package 50 by adhering a lower surface 76A of the lower part 76 to an upper surface 52D of the cylindrical portion 52. The other structures of the lower part 76 are the same as the structures of the inner part 71 of the third embodiment and the lower part 61 of the on-off valve 60 of the first embodiment.

The pressure sensor device described above can also be described as follows.

A pressure sensor device of a first aspect comprises: a base substrate; a detecting element mounted on an upper surface of the base substrate and that includes a detecting portion that detects pressure; a resin package on the upper surface of the base substrate and that has an exposure hole that exposes the detecting portion, the detecting element being embedded in the resin package; and an on-off valve disposed so as to close the exposure hole, wherein the on-off valve includes: a membrane that includes an outer surface facing an outside of the pressure sensor device, and a communication path that is partly formed by an inner surface of the membrane and allows the detecting portion to communicate with the outside of the pressure sensor device, the inner surface being opposite the outer surface, and wherein the inner surface closes the communication path when the membrane is flexed by pressure that acts upon the outer surface.

In a pressure sensor device of a second aspect according to the pressure sensor device of the first aspect, the on-off valve includes: a lower part that opposes the detecting element, and an upper part on a side of the lower part opposite the detecting element so as to face the outside of the pressure sensor device, the upper part including the membrane, wherein the communication path includes: an upper through hole on an outer side of the membrane in the upper part, that opens toward the outside of the pressure sensor device, and that extends through the upper part, an inner space between the membrane and the lower part and that communicates with the upper through hole, and a lower through hole that extends through the lower part and that includes an upper side opening and a lower side opening, the upper side opening opens into the inner space at a location where the upper side opening opposes the membrane, the lower side opening opens toward the detecting element, and wherein the inner surface closes the upper side opening of the lower through hole when the membrane is flexed by the pressure that acts upon the outer surface.

In a pressure sensor device of a third aspect according to the pressure sensor device of the first aspect or the second aspect, the membrane includes a thick film portion positioned at a central portion of the membrane, and a thin film portion that surrounds the thick film portion and is thinner than the thick film portion, and the inner surface of the membrane that is positioned at the thick film portion closes the communication path.

In a pressure sensor device of a fourth aspect according to the pressure sensor device of any one of the first aspect to the third aspect, when a liquid that has come into contact with the on-off valve has entered the communication path from the outside of the pressure sensor device, the inner surface of the membrane flexed by pressure of the liquid acting upon the outer surface closes the communication path before the liquid reaches a closing position where the communication path is closed by the inner surface.

A pressure sensor device of a fifth aspect according to the pressure sensor device of any one of the first aspect to the fourth aspect, further comprises: a closing film that closes an opening of the communication path that opens toward the outside of the pressure sensor device, the closing film being constructed so as to allow a gas to pass and not allow a liquid to pass therethrough.

In a pressure sensor device of a sixth aspect according to the pressure sensor device of any one of the first aspect to the fifth aspect, wherein the detecting element and the on-off valve constitute a micro electro mechanical system.

In a pressure sensor device of a seventh aspect according to the pressure sensor device of any one of the first aspect to the sixth aspect, the on-off valve is disposed at an upper portion of the exposure hole and opposes the detecting portion with a lower portion of the exposure hole being interposed therebetween.

In a pressure sensor device of an eighth aspect according to the pressure sensor device of any one of the first aspect to the seventh aspect, the resin package includes: a base portion on the upper surface of the base substrate, and a cylindrical portion that projects upward from the base portion and that defines the exposure hole, wherein the base portion extends outward from an outer side surface of the cylindrical portion, and the on-off valve includes: an inner part that is positioned at an inner portion of the exposure hole, and an outer part that is positioned on an upper side of the exposure hole and that is supported by the cylindrical portion, and wherein at least a part of the outer part extends outward from the outer side surface of the cylindrical portion.

Note that, by combining as appropriate any of the embodiments among the various embodiments above, effects of each of these embodiments can be exhibited.

Although the present disclosure has been sufficiently described in relation to preferred embodiments while referring to the drawings as appropriate, it is obvious to persons skilled in the art that various modifications and amendments are possible. It is to be understood that, as long as such modifications and amendments do not depart from the scope of the attached claims, such modifications and amendments are included in the scope of the claims.

### REFERENCE SIGNS LIST

10 pressure sensor device
20 base substrate
20A upper surface
30 detecting element
33 detecting portion
50 resin package
51 base portion
52 cylindrical portion
52B outer side surface
52C exposure hole
60 on-off valve
61 lower part
62 upper part
63 membrane
63A upper surface (outer surface)
63B lower surface (inner surface)
631 thick film portion
632 thin film portion
65 communication path
65A upper through hole
65B inner space
65C lower through hole
65Ca upper side opening
65Cb lower side opening
66 blocking film
70 on-off valve
71 inner part
72 outer part

1. A pressure sensor device comprising:
a base substrate;
a detecting element mounted on an upper surface of the base substrate and that includes a detecting portion that detects pressure;
a resin package on the upper surface of the base substrate and that has an exposure hole that exposes the detecting portion, the detecting element being embedded in the resin package; and
an on-off valve disposed so as to close the exposure hole, wherein the on-off valve includes:
a membrane that includes an outer surface facing an outside of the pressure sensor device, and
a communication path that is partly formed by an inner surface of the membrane and allows the detecting portion to communicate with the outside of the pressure sensor device, the inner surface being opposite the outer surface, and
wherein the inner surface closes the communication path when the membrane is flexed by pressure that acts upon the outer surface.

2. The pressure sensor device according to claim 1,
wherein the on-off valve includes:
a lower part that opposes the detecting element, and
an upper part on a side of the lower part opposite the detecting element so as to face the outside of the pressure sensor device, the upper part including the membrane,
wherein the communication path includes:
an upper through hole on an outer side of the membrane in the upper part, that opens toward the outside of the pressure sensor device, and that extends through the upper part,
an inner space between the membrane and the lower part and that communicates with the upper through hole, and
a lower through hole that extends through the lower part and that includes an upper side opening and a lower side opening, the upper side opening opens into the inner space at a location where the upper side opening opposes the membrane, the lower side opening opens toward the detecting element, and
wherein the inner surface closes the upper side opening of the lower through hole when the membrane is flexed by the pressure that acts upon the outer surface.

3. The pressure sensor device according to claim 2, wherein the lower part is positioned in the exposure hole and an upper part is positioned outside the exposure hole.

4. The pressure sensor device according to claim 2, wherein the lower part and the outer part are positioned outside of the exposure hole.

5. The pressure sensor device according to claim 2, wherein the membrane includes:
a thick film portion positioned at a central portion of the membrane, and
a thin film portion that surrounds the thick film portion and is thinner than the thick film portion, and
wherein, the inner surface of the membrane that is positioned at the thick film portion closes the communication path.

6. The pressure sensor device according to claim 1, wherein the membrane includes:
a thick film portion a central portion of the membrane, and
a thin film portion that surrounds the thick film portion and is thinner than the thick film portion, and
wherein, the inner surface of the membrane that is positioned at the thick film portion closes the communication path.

7. The pressure sensor device according to claim 1, wherein, when a liquid that has come into contact with the on-off valve has entered the communication path from the outside of the pressure sensor device, the inner surface of the membrane flexed by pressure of the liquid acting upon the outer surface closes the communication path before the liquid reaches a closing position where the communication path is closed by the inner surface.

8. The pressure sensor device according to claim 1, further comprising:
a closing film that closes an opening of the communication path that opens toward the outside of the pressure sensor device, the closing film being constructed so as to allow a gas to pass and not allow a liquid to pass therethrough.

9. The pressure sensor device according to claim 1, wherein the detecting element and the on-off valve constitute a micro electro mechanical system.

10. The pressure sensor device according to claim 1, wherein the on-off valve is disposed within the exposure hole.

11. The pressure sensor device according to claim 10, further comprising:
a closing film that closes an opening of the communication path that opens toward the outside of the pressure sensor device, the closing film being constructed so as to allow a gas to pass and not allow a liquid to pass therethrough.

12. The pressure sensor device according to claim 1, wherein the on-off valve includes an inner part in the exposure hole and an outer part outside the exposure hole.

13. The pressure sensor device according to claim 1, wherein the on-off valve includes a lower part positioned outside of the exposure hole and an outer part positioned outside of the exposure hole.

14. The pressure sensor device according to claim 1, wherein the on-off valve is disposed at an upper portion of the exposure hole and opposes the detecting portion with a lower portion of the exposure hole being interposed therebetween.

15. The pressure sensor device according to claim 1,
wherein the resin package includes:
a base portion on the upper surface of the base substrate, and
a cylindrical portion that projects upward from the base portion and that defines the exposure hole,
wherein the base portion extends outward from an outer side surface of the cylindrical portion,
wherein the on-off valve includes:
an inner part that is positioned at an inner portion of the exposure hole, and
an outer part that is positioned on an upper side of the exposure hole and that is supported by the cylindrical portion, and
wherein at least a part of the outer part extends outward from the outer side surface of the cylindrical portion.
